(19) United States
(12) Patent Application Publication
(10) Pub. No.: US 2003/0087534 A1
(43) Pub. Date: May 8, 2003

(54) Surface modification for barrier to ionic penetration

(75) Inventors: Anupama Mallikarjunan, Troy, NY (US); Shyam P. Murarka, Clifton Park, NY (US); Toh-Ming Lu, Loudonville, NY (US)

Correspondence Address: HESLIN ROTHENBERG FARLEY & MESITI PC, 5 COLUMBIA CIRCLE, ALBANY, NY, 12203, US

(73) Assignee: Rensselaer Polytechnic Institute, Troy, NY

(21) Appl. No.: 10/241,801

(22) Filed: Sep. 10, 2002

Related U.S. Application Data
(60) Provisional application No. 60/318,001, filed on Sep. 10, 2001.

(51) Int. Cl. H01L 21/31; H01L 21/469

(52) U.S. Cl. 438/781; 438/780

(57) ABSTRACT

A method for preventing migration of metal ions into a dielectric layer comprising low-κ siloxane polymer includes treating at least one surface of the dielectric layer with a plasma selected from nitrogen, nitrogen oxides, noble gases and mixtures thereof, and forming on the treated surface a barrier layer. The barrier layer prevents migration of metal ions into the dielectric layer.

### CROSS-REFERENCE TO RELATED APPLICATIONS

This application claims the benefit of U.S. Provisional Application No. 60/318,001, filed Sep. 10, 2001, the contents of which are hereby incorporated by reference in its entirety.

### TECHNICAL FIELD

The present invention relates to barriers to ion penetration for low k siloxane dielectrics used in microelectronics applications.

### BACKGROUND

High-performance microprocessors demand on-chip interconnections that operate with low interconnect delay and cross-talk noise and, in addition, consume less power. One way to achieve this improved interconnect performance is implementation of copper as the interconnect metal and low dielectric constant (low κ) materials as the isolating medium. In this context, low-κ means a dielectric constant less than that of silicon dioxide dielectrics, which has a dielectric constant of about 3.9. Several types of low-κ materials are currently of interest commercially. One type is termed herein inorganic silicon or siloxane polymer because the polymer contains very little carbon. These are derived from siloxane monomers such as hydrogen silsesquioxane (HSQ), and are also referred to in the industry as spin-on glasses (SOG). HSQ is available from Dow Corning as FOX™. Another type is carbon-containing siloxane polymers referred to herein as organic siloxane polymers. These are also known as organosiloxane polymers, hybrid materials or SiOCH dielectrics because they contain organic carbon as well as inorganic Si—O— moieties. Examples of these include siloxane polymers derived from methyl silsesquioxane (MSQ), materials known as hybrid organosiloxane polymers (HOSP), which are derived from HSQ and MSQ, and materials known as organosilicate glasses, such as Trikon Flowfill™, Black Diamond™, available from Applied Materials, SantaClara, Calif., and Coral™, available from Novellus, Inc. A third type is organic low-κ polymers such as FLARE™, a poly (arylene) ether available from Allied Signal, Advanced Microelectronic Materials, Sunnyvale, Calif., BCB (divinylsiloxane bisbenzocyclobutene) and Silk™, an organic polymer similar to BCB, both available from Dow Chemical Co., Midland, Mich.

Because ion penetration into dielectrics from surrounding metal such as aluminum or tantalum, but especially from copper interconnects, can increase leakage and lead to premature breakdown, barriers to ion penetration are required between metal and dielectric. Typically, dielectric barriers have higher dielectric constant (κ) value, while metallic barriers have high resistivity, and overall, the on-chip interconnect delay increases due to the presence of these barriers. Scaling down the interconnect dimensions requires a proportional shrinkage in the deposited barrier thickness and it is a growing challenge to deposit thinner, but equally effective conventional barriers in a conformal and defect-free manner. This approach is therefore not extendible indefinitely. An alternative approach to form a thin, conformal and effective barrier is thus much needed. Hence, development of near zero thickness liners or ultra-thin barriers using new approaches such as atomic layer deposition or surface modification is critical.

While some work has also been reported on blocking copper metallic diffusion into low κ polymers by means of plasma treatment, formation of a barrier layer at the interface by depositing a metal on a plasma-treated dielectric has not been reported. See, for example, publications of Liu et al., who report that H₂ plasma passivation or NH₃ plasma nitridation of a hydrogen silsesquioxane (HSQ) film can block copper diffusion (Liu, et al., IEEE Trans. Electron Dev. 47, 1733 (2000); Liu, et al., J. Electrochem. Soc. 147, 1186 (2000)). However, no work has been reported on blocking the motion of metal ions under the influence of an electric field. In actual application, the interconnect dielectric is subject to a constant or changing electric field, and it is important to ensure that metal ions from the current carrying interconnect lines do not penetrate the dielectric and drift under applied bias. Such metal drift could cause excess leakage, and premature breakdown of the dielectric. Therefore, there is a need for a method to block the movement of metal ions into a low-K dielectric, particularly under applied electrical bias.

### SUMMARY OF THE INVENTION

It has been unexpectedly discovered that treatment of a low-κ siloxane dielectric with a plasma and forming a barrier layer on the dielectric can effectively block the movement of metal ions, including copper ions, into an organosiloxane dielectric, particularly under applied electrical bias. Accordingly, the present invention relates to a method for preventing migration of metal ions into a dielectric layer comprising low-κ siloxane polymer. In one embodiment, the method includes treating at least one surface of the dielectric layer with a plasma selected from nitrogen, nitrogen oxides, noble gases and mixtures thereof, and forming on the treated surface a barrier layer. The barrier layer prevents migration of metal ions into the dielectric layer. In another embodiment, the method includes treating at least one surface of the dielectric layer with an ammonia plasma, and forming on the treated surface a barrier layer; copper may be deposited over the barrier layer. In yet another embodiment, the method includes treating at least one surface of the dielectric layer with a plasma other than an ammonia plasma and forming a barrier layer; copper may be deposited over the barrier layer. In all cases, the barrier layer prevents migration of metal ions into the dielectric layer.

### BRIEF DESCRIPTION OF THE DRAWINGS

FIG. 1: Configuration used for plasma surface modification experiments, along with illustration of sheath potential.

FIG. 2: FTIR spectrum of HOSP, showing prominent Si—O bonding with additional Si—C and Si—H.

FIG. 3: Plasma damage in aluminum/HOSP capacitors: (a) Stretchout of C-V curve after treatment in etching mode with sample biased and (b) Hysteresis after N₂0 plasma treatment with sample grounded.

FIG. 4: Effect of (a) N₂ plasma treatment at room temperature or (b) Ar plasma treatment at room temperature or (c) N₂ plasma treatment at 110° C. (at 0.9 torr for 1 min) on charges detected in aluminum/HOSP capacitors. Mobile ions detected were dramatically reduced in plasma-treated samples. Bias temperature stressing (BTS) was performed at 150° C. and 0.5 MV/cm.

FIG. 5: Triangular voltage sweep (TVS) results on plasma treated HOSP, showing smaller peak and less increase in peak area with BTS when compared to untreated HOSP. TVS was done at 150° C. and 1 V/s sweep after intervals of biasing at 150° C. and 0.5 MV/cm.

FIG. 6: Nitrogen peak detected by XPS at ˜400 eV binding energy only for N₂ plasma treatment at 110° C., indicating the presence of a nitrided layer on the surface.

FIG. 7: Increase in binding energy of Si 2p peak from 101.4 eV in untreated HOSP sample to 103.3 eV after Ar plasma treatment, indicating the formation of a SiO₂ like surface.

FIG. 8: Surface composition measured by XPS before and after plasma treatments in N₂ or Ar ambient. Increase in oxygen/carbon ratio was observed after plasma treatment.

FIG. 9: Increase in binding energy of Si 2p peak from 101.4 eV in untreated HOSP sample up to 103.3 eV after Ar plasma treatment, indicating the formation of SiO₂ like surface.

FIG. 10: Effect of plasma treatment on (a) refractive index and (b) dielectric constant values. Minimal changes were detected for room temperature nitrogen plasma treated samples.

### DETAILED DESCRIPTION OF THE INVENTION

The present invention relates to methods for preventing migration of metal ions, and especially copper ions, into a low-κ siloxane dielectric. In particular, migration or diffusion of metal ions under an applied electrical bias can be prevented or blocked. The methods involve plasma treatment of the dielectric to modify the chemical composition/structure of the dielectric surface, without significantly affecting bulk properties of the dielectric layer. Formation of the barrier layer is typically self-limiting, that is, limited to a few monolayers, and the barrier layer is typically thermodynamically stable at fabrication and operating temperatures. In some embodiments, a barrier or passivation layer is formed directly by the plasma treatment, while in others, the plasma treatment activates the surface for reaction with metal atoms, whereby a metal-containing barrier layer may be formed.

Low-κ siloxane dielectrics that may be treated according to the methods of the present invention include inorganic and organic siloxane polymers. These may be derived from HSQ, MSQ, or mixtures of these, particularly HOSP. Suitable organic siloxane polymers also include the organosilicate glasses such as Trikon Flowfill™, Black Diamond™, and Coral™.

In a first embodiment, the present invention relates to a method for preventing migration of metal ions into a dielectric layer comprising low-κ siloxane polymer. The method includes treating at least one surface of the dielectric layer with a plasma selected from nitrogen, nitrogen oxides, noble gases and mixtures thereof, and forming on the treated surface a barrier layer. The barrier layer typically includes a heavily atomically damaged surface, an oxygen rich layer, and/or an oxidized layer. In addition, one or more oxide-forming or silicon oxideforming metals may be deposited on the treated surface to form the barrier layer. In this case, it is believed that the metal(s) form metal oxide(s) or metal silicon oxide(s) on the surface. The barrier layer, formed solely by plasma treatment or formed by plasma treatment in combination with formation of a metal layer, prevents migration of metal ions into the dielectric layer.

Plasma gases suitable for treating the surface prior to forming a metal oxide or metal silicon oxide barrier layer on the treated or modified surface include nitrogen, nitrogen oxides and noble gases. Nitrogen oxides are N₂O, NO₂ and NO; noble gases include argon, neon, krypton, xenon, radon and helium.

Suitable metals for forming a metal oxide or metal silicon oxide barrier layer are those that form an oxide or a mixed oxide such as a metal silicon oxide by chemically reducing oxygen-containing moieties on the surface, especially moieties containing silicon-oxygen bonds. In some embodiments, the metal(s) may be aluminum, titanium, hafnium, zirconium, tantalum or mixtures thereof, aluminum is a particularly preferred metal. The barrier layer may be formed by depositing a layer of the metal(s) on the plasma-treated surface, by CVD or PVD methods. During the deposition, it is believed the metal reacts with the plasma-treated surface to form a few monolayers of one or more metal oxides or metal silicon oxides. A layer of the metal(s) may also be formed over the barrier layer, either during the deposition or subsequent to it.

The function of the metal oxide or metal silicon oxides barrier layer is to prevent migration of metal ions into the dielectric layer. These metal ions may be derived from the metal of which the metal or metal silicon oxide barrier layer is composed, or it may be a different metal or metals. In some embodiments, a copper film or layer is disposed over the barrier layer and migration of copper ions into the dielectric is prevented. The copper layer may be disposed directly on the barrier layer or on a layer of the metal(s) making up the metal oxide or metal silicon oxide of the barrier layer.

In another embodiment, the present invention relates to a method for preventing migration of metal ions into a dielectric layer comprising a low-κ siloxane polymer, without significantly affecting properties of the dielectric layer. The method includes treating at least one surface of the dielectric layer with an ammonia plasma, and forming on the treated surface a barrier layer; copper may be deposited over the barrier layer, if desired. The barrier layer may include a heavily atomically damaged surface, a nitrogen rich layer, and/or a nitride layer that may form metal nitride(s) or metal silicon nitride(s), and prevents migration of metal ions into the dielectric layer. The metal may be tantalum, titanium, or a mixture thereof.

In yet another embodiment, the present invention relates to a method for preventing migration of metal ions into a dielectric layer comprising a low-κ siloxane polymer, without significantly affecting properties of the dielectric layer. The method includes treating at least one surface of the dielectric layer with a plasma other than an ammonia plasma and forming a barrier layer. If desired, a copper layer may be deposited over the barrier layer. The barrier layer may include an atomically damaged surface, a nitrogen rich layer, and/or a nitride barrier layer which prevents migration of metal ions into the dielectric layer. It is believed that plasma treatment introduces nitrogen atoms into the chemical structure of the surface of the dielectric, forming a nitride-based barrier layer. The plasma gas may be nitrogen or one or more nitrogen oxides, and in particular, nitrogen. The barrier layer may be formed by depositing at least one metal on the treated surface, and the metal(s) may be tantalum, titanium or a mixture of the two.

### EXAMPLES

### Example 1

### Preparation and Study of HOSP Dielectric

HOSP capacitors were prepared on 50 nm thermally oxidized n-100 Si substrates. The polymer was spun at 3000 rpm, and then sequentially baked at 150, 200 and 350° C. each for 1 min in N₂ ambient. The curing step was done at 400° C. in N₂ ambient for 1 h. The final thickness (200 nm) and refractive index (1.38) were measured using a 44 wavelength spectroscopic ellipsometer (J. A. Wollam Co. Inc.) with a spectral range from 404 to 740 nm. Refractive index (RI) measurements were preformed at a wavelength of 634.1 nm. Chemical bonding structure was studied using Fourier transform infrared (FTIR) spectroscopy performed on a Mattson Galaxy Series 3000 spectrometer. Transmission spectra at normal incidence were collected at a 4 cm⁻¹ resolution.

### Example 2

### Plasma Treatment Conditions

Samples were divided into batches for N₂, Ar, N₂O, or O₂ plasma treatment. All plasma treatments were performed at 900 mT pressure in the deposition chamber of a Plasmatherm 73 reactor. The gas flow rate was 300 sccm and plasma exposure time was limited to 1 min. RF power (30 or 200 W) was applied to the upper electrode and the wafers were placed on the bottom electrode which was grounded. Unless stated otherwise, all treatments were performed at room temperature. A cleaning step consisting of 45 min in CF₄ followed by 90 min in N₂O at 200 W power and 1 torr pressure was performed before the samples were loaded. This step was necessary to minimize cross-contamination, especially fluorine, from the plasma reactor.

### Example 3

### Surface Study by XPS

X-ray photoelectron spectroscopy (XPS) was carried out to analyze the change in surface composition after plasma treatment. The system was a Perkin Elmer 5500, which used monochromatized Mg Kct line at 1253.6 eV as the X-ray source. The take-off angle was 45°. The base vacuum in the XPS chamber was at least 1×10⁻⁹ torr. High resolution spectra were corrected for charging by referencing the adventitious C (1s) peak (separable from the large C (1s) peak in the polymer) to a binding energy of 284.6 eV.

### Example 4

### Electrical Methods for Ion Penetration Study

Capacitors were fabricated by deposition of top gate metal through a shadow mask containing circular holes of diameter ranging from 0.5-1.5 mm. aluminum was sputter deposited at 2.5 kW power in a Consolidated Vacuum Corporation (CVC) DC magnetron system after the chamber was pumped down to a base pressure of 1×10⁻⁶ torr or better. The fabricated metal-insulator-semiconductor (MIS) capacitors were annealed in Ar (containing 3% H₂) ambient at 300° C. for 1 h. BTS C-V measurements were made on HP 4280A 1 MHz Capacitance Meter/CV Plotter. A small a.c. signal of 10 mV r.m.s was superposed on the applied d.c. bias. TVS scans were performed using the HP 4140B pA Meter. A Labview program running on an IBM-compatible PC was used to measure and record the data. For both tests, the capacitors were vacuum-held on an MSI Electronics Light Shield/ Hot Chuck and were under nitrogen purge throughout the experiment. BTS experiments were performed with HOSP MIS structures at a temperature of 150° C. and bias of 0.5 MV/cm. The samples were biased at high temperatures, water-cooled rapidly down to room temperature (with bias on) at periodic intervals and C-V measurements were conducted. Final results are presented in terms of number of excess charges/cm² detected in the capacitor at the specified time interval after BTS. TVS voltage sweeps were made at 150° C., and sweep rate of 1 V/s. After an initial bias voltage (equivalent to 0.5 MV/cm) was applied for a given interval, voltage scans were performed at high temperature from +30 V to −60 V to detect all possible peak features. The current (I) values were converted to capacitance (C) using the relation I=aC, where a is the voltage sweep rate.

Results And Discussion

FTIR study of cured HOSP showed the presence of both cage-like and network Si—O bonds, in addition to Si—C and Si—H bonds (FIG. 1). No moisture or silanol groups were detected in the polymer bulk. From XPS, the surface atomic ratio of Si:O:C was found to be 1:1.3:0.7, similar to SiO₂.

Plasma treatment was attempted with the goal of removing organic groups from HOSP surface and thereby converting the surface to resemble SiO₂ more closely. Aluminum could then reduce the silica layer to form an aluminum oxide barrier layer. However, plasma damage could occur in the polymer bulk due to the bombardment of energetic particles and photons. The damage could be caused by ions, electrons, UV photons and soft X-rays. Ions generally have energies <10 eV, but ions in the high-end energy distribution tail could have as much as 1000 eV, depending on the sheath potential. Atomic displacements and generation of electron-hole pairs (EHPs) are some of the damaging structural changes that can potentially be reversed by annealing the polymer at high temperatures. EHPs can be generated either by primary ionization from the UV and X-ray photons or secondary ionization where electrons formed by primary processes can create defect centers. Contamination and breakdown of thin insulating films due to charging are some of the irreversible effects of plasma treatment. Electrically, the damage may manifest itself in effects such as

i. increase in dielectric constant

ii. increase in leakage current

iii. distortions in C-V characteristics.

The first two effects have been explored in detail by many researchers: O₂ plasma treatment has led to increase in K for hydrogen silsesquioxane (HSQ) and, in addition, increase in leakage in aerogel material. Severe increase in moisture absorption has been observed in HOSP after O₂ plasma treatment. Treatment with N₂O and N₂ plasma has increased K and leakage of HSQ material, respectively. Hydrogen plasmas were found to have passivating effects on HSQ, methyl silsesquioxane (MSQ), and aerogels.

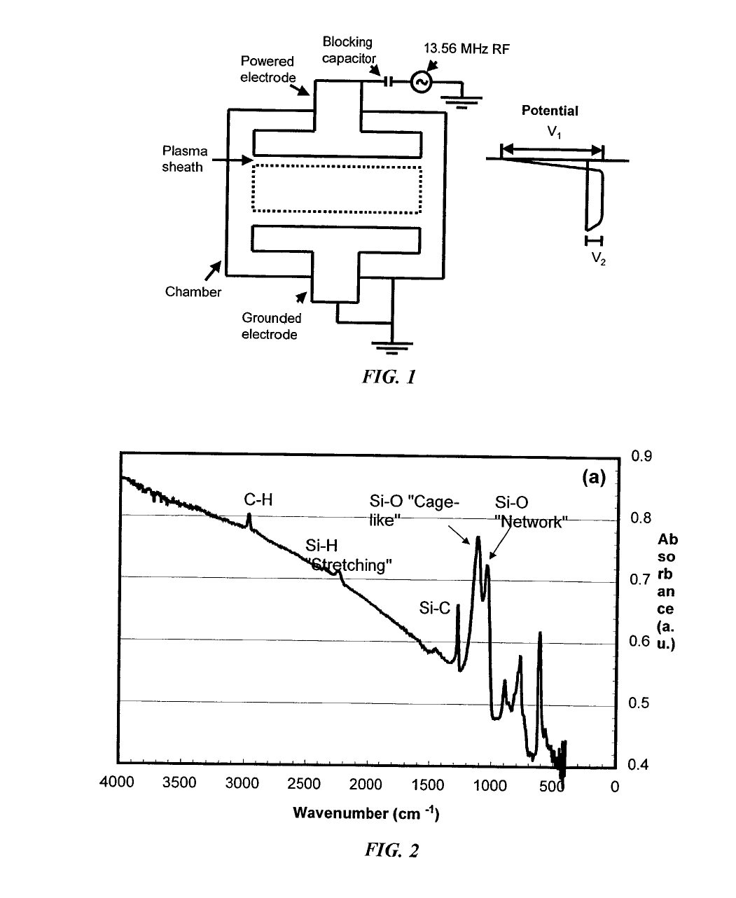

It was found that leakage currents did not show any increase after plasma treatment. This could, however, be explained as the effect of the underlying thermal oxide in the MIS capacitor. Changes in K were also monitored. C-V stretchout (FIG. 2) was observed when plasma treatment was performed in the etching mode, i.e., with the bias applied to the bottom electrode. (In this case, the HOSP capacitor was prepared on p-Si substrate). Stretchout implies either increase in interface state density or lateral non-uniformities in interface fixed charge. Annealing up to 300° C. did not eliminate this effect. If the C-V curve is non-ideal, it is not possible to monitor changes in the flatband voltage upon BTS. The plasma etching mode was designed to bombard and remove material, and it is not surprising that there were residual electrical damage to the samples. For this reason, all further experiments were performed with the bottom electrode grounded to the chamber. In this configuration, the bottom electrode area was increased, and the ion bombardment energy at the polymer surface is reduced.

For surface modification or surface activation, non polymer-forming plasmas such as O₂, N₂, nitrogen oxides and inert plasmas are preferred. In these cases, bombardment leads to creation of radicals on the polymer surface. These radicals react with the active species in the plasma, and chemical functional groups are created on the surface. In addition, weakly bonded layers or contamination may be removed from the surface. Oxygen and nitrogen plasmas increase the hydrophilic character of the surface by incorporation of species such as carboxyl, carbonyl and hydroxyl groups. Surface crosslinking and incorporation of oxygen are also known to occur with oxygen plasmas. With inert gases, physical ablation (by ion sputtering and impinging of energetic neutral species) and free radical formation are the dominant effects. The ablated fragments can also be redeposited or reincorporated in a highly crosslinked state.

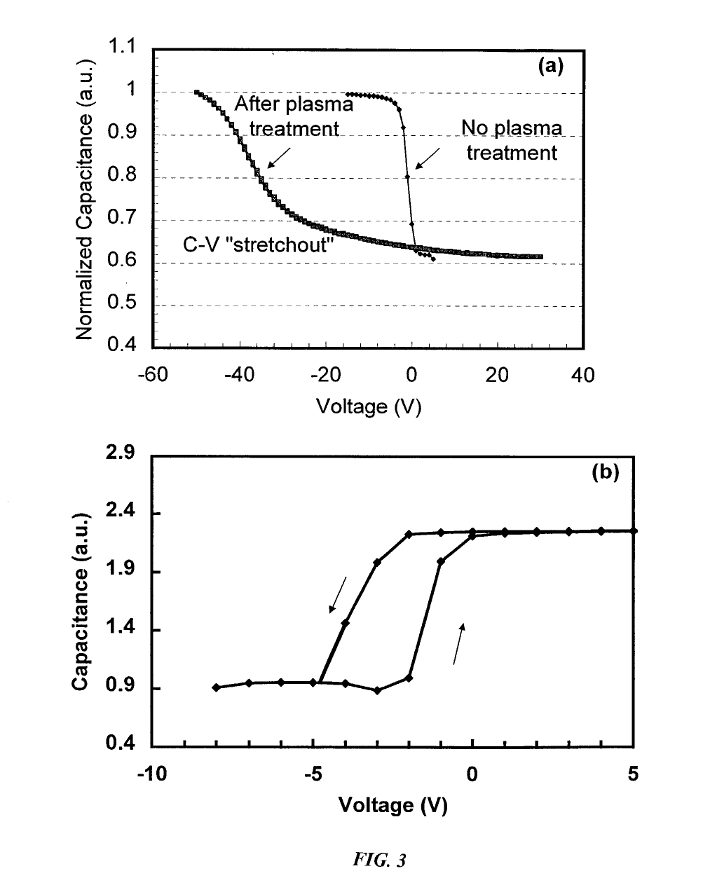

At first, the effects of O₂ and N₂0 plasmas were investigated. High etch rates were obtained with O₂ plasma (>27 nm/min) and N₂O plasma (5-8 nm/min); and both O₂ and N₂O plasma treatments resulted in hysteresis in C-V characteristic (FIG. 3). Again, these effects preclude the study of mobile ion movement using BTS. Further studies were pursued with N₂ and Ar plasmas, as low etch rates (0-5 nm/min) and no distortions in C-V characteristics were observed.

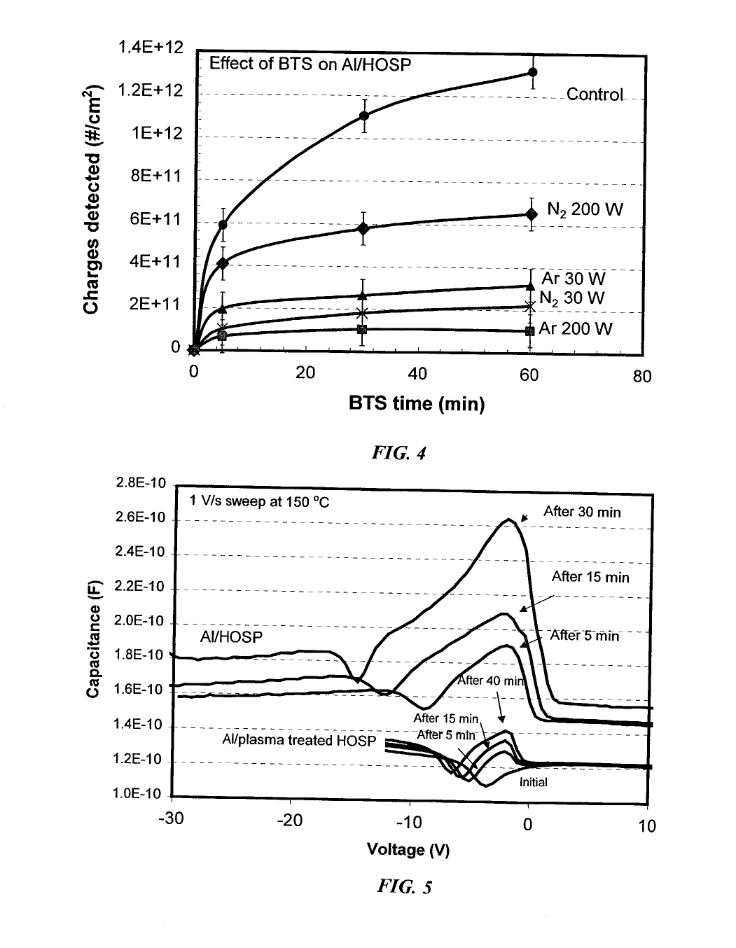

In FIGS. 4 and 5, results of BTS at 150° C. and 0.5 MV/cm are shown for control (no treatment) and room temperature plasma-treated samples with aluminum gate metal. The number of charges detected after BTS was lower for all plasma-treated samples compared to the control sample. (No systematic effect of plasma power was detected in these experiments).

As discussed earlier, plasma treatment could also improve crosslinking at the surface. A crosslinked surface could have barrier properties because of its improved density. Experiments on Cu drift characterization into Ar plasma treated HOSP capacitors were performed. To begin with, Cu drift through HOSP was found to be much lower than that seen with aluminum and only 5×10 charges/cm² were detected after 60 min BTS. Plasma treatment did not significantly improve this behavior. Thus, the benefits of crosslinking, if any, were not detected in our experiments. An improvement was noticed in Cu drift resistance in only one case, when the N₂ plasma-treatment was performed at 110° C. on HOSP. However, the difference was well within the magnitude of error. Dramatic reduction in aluminum penetration was nevertheless visible in this case too.

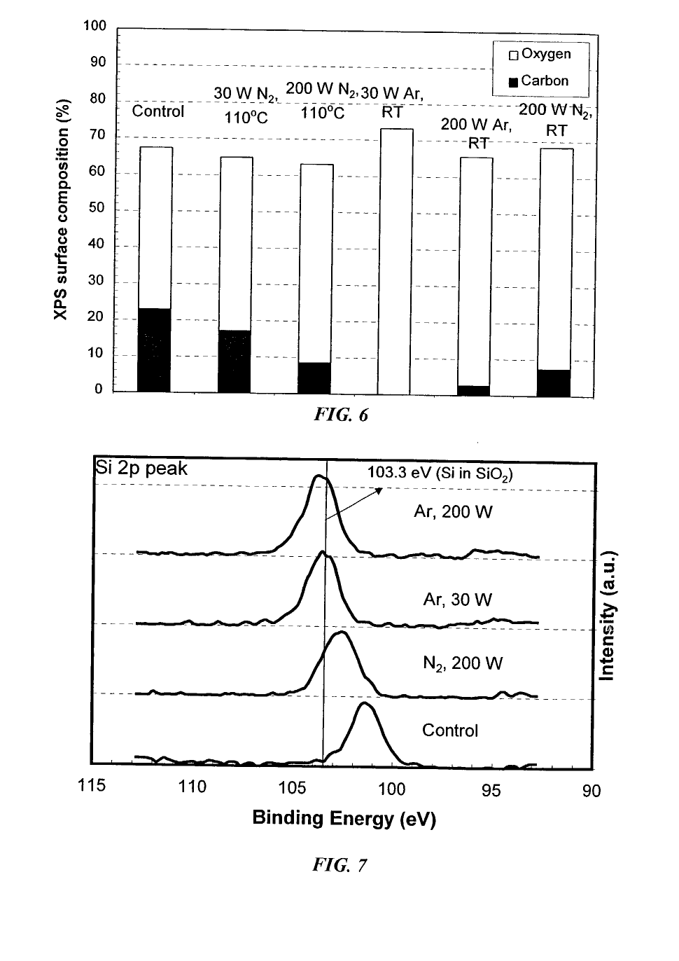

TVS was carried out at 150° C. and 1 V/s sweep on selected aluminum/plasma treated HOSP capacitors. Large TVS peaks were detected for untreated HOSP capacitors, whereas much smaller peaks were detected for N₂ plasma treated HOSP (FIG. 6). It is clear that the mobile species responsible for observed BTS and TVS instabilities was dramatically reduced upon plasma treatment.

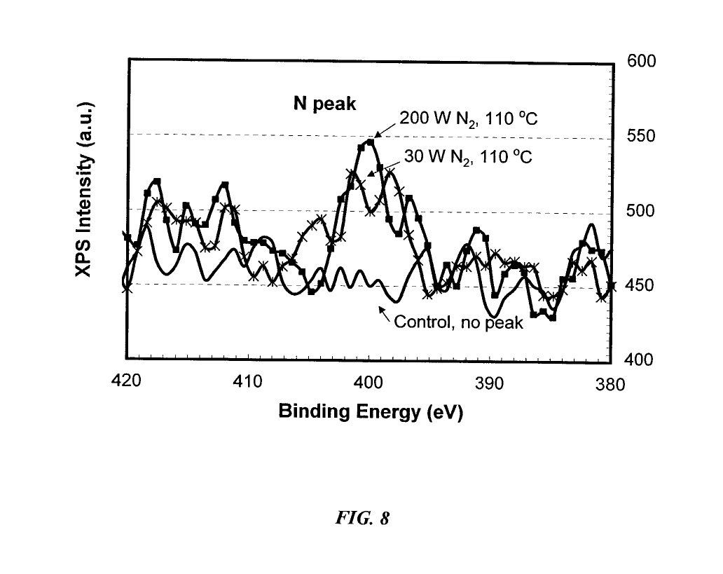

The nature of the chemical changes occurring on the surface of HOSP was investigated using XPS. In FIG. 7, the XPS surface concentrations of carbon and oxygen are plotted for the different plasma treatments. In all cases, the fraction of carbon detected decreased, while that of oxygen increased. The fraction of Si detected on the surface was nearly constant at ˜30%. Thus, it appears that plasma treatments made the HOSP surface oxygen-rich, and reduced the organic components. Binding energy of the Si 2p peak also shifted from 101.4 eV for the control sample towards higher values after plasma treatment, closer to 103.3 eV, the binding energy of Si in SiO₂ (FIG. 8). Thus, there was a change in bonding chemistry at the surface, making it more SiO₂ rich. The mechanism of incorporation of oxygen could be either due to post-plasma exposure to atmosphere or oxygen-containing species in the plasma from residual gases. The effect of plasma treatment on Si—H bonding could not be determined in this study.

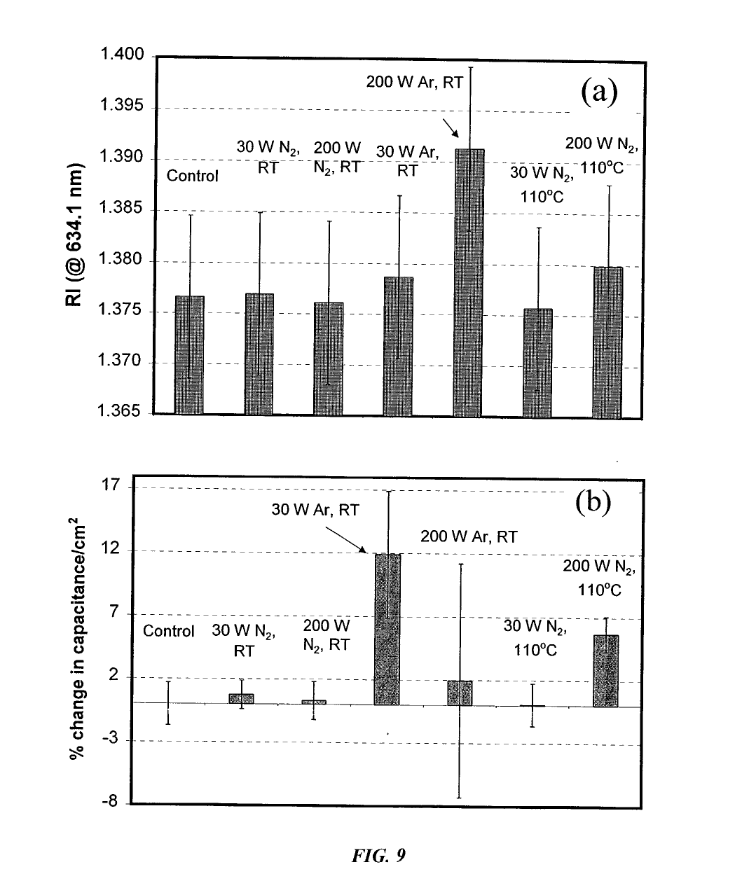

In the case of N₂ plasma treatment at room temperature, no incorporation of nitrogen was detected on the surface. A small nitrogen signal was however detected when the plasma treatment temperature was increased to 110° C. (FIG. 9). XPS sputter depth profiling showed that this nitrogen was present in the sub-surface (˜3 nm) of the polymer too. The thickness values of these nitrided layers, estimated from secondary ion mass spectroscopy (SIMS) depth profiles, were both high (10 and 35 nm). Based on the improvement in copper barrier property of the nitrided surface, improved nitridation of the surface can be employed as a barrier technique against copper drift in HOSP.

Changes in refractive index (RI) and dielectric constant (κ) values were monitored for all plasma treatments, and are presented in FIG. 10. Compared to N₂, Ar plasma treatment resulted in greater variation; and increase in refractive index (RI) and in κ. The dominant ionic species expected in each of the above plasmas is N₂⁺ and Ar⁺, respectively. The ion energy distribution function and ion flux at the substrate surface are influenced by ion charge, mass and collisional cross sections (apart from parameters such as plasma voltage). It has been reported that under identical applied plasma conditions, electron as well as ion densities in N₂ plasma were as much as one order of magnitude lower than in Ar plasma. Such a mechanism could account for the better surface modification and increased bulk damage in Ar plasma. The 30 W N₂ treatment at room temperature resulted in optimal properties: no change in RI, minimal change in κ and dramatic reduction in charges detected after BTS. The results show that it is possible to find ideal plasma conditions under which minimum damage occurs. Although these results apply to one specific hybrid polymer, we believe that the strategy can be tailored to achieve suitable surface modification in a variety of low κ materials.

When aluminum is deposited on SiO₂, a thin, continuous and self-limiting aluminum oxide layer, formed by reduction of SiO₂, is believed to be responsible for the excellent diffusion barrier properties on SiO₂. This reaction is

3SiO₂+4Al→2Al₂O₂O₃+3Si

The same behavior is not expected with organic polymers or hybrids, as the surface may be terminated with oxygen-free organic groups. If the surface of the hybrid siloxane polymer can be modified to eliminate the organic groups and increase the oxygen content, then it resembles SiO₂ more closely. When aluminum is deposited on this modified layer, a thin intrinsic barrier against aluminum penetration can be created. The goal of this work was thus two-fold

(a) to attempt plasma-modification of the HOSP surface by eliminating the methyl groups and hydrogen; and leaving behind an SiO₂-rich surface

(b) and to verify if the modified layer acts as aluminum ion-penetration barrier.

Using sensitive electrical measurements, we were able to demonstrate the ion barrier property of plasma-modified siloxane dielectric. The plasma-treatment conditions were chosen to minimize damage to bulk dielectric and achieve only surface activation. With high chamber pressure and low plasma power, the mean free path and energy of plasma ions is low, minimizing deleterious effects. A short (1 min) low power (30 W) N₂ plasma treatment at high pressure (0.9 torr) was effective as an aluminum ion penetration barrier, without significantly increasing the refractive index or dielectric constant value of HOSP. Surface modification is thus a powerful strategy to realize the future requirement of zero-thickness barriers, provided it also leads to required adhesion.

In the claims:

1. A method for preventing migration of metal ions into a dielectric layer comprising a low-κ siloxane polymer, the method comprising treating at least one surface of the dielectric layer with a plasma selected from the group consisting of nitrogen, nitrogen oxides, noble gases and mixtures thereof and forming a barrier layer on the treated surface;
whereby the barrier layer prevents migration of metal ions into the dielectric layer.

2. A method according to claim 1, additionally comprising depositing at least one oxide-forming or silicon oxide-forming metal on the treated surface to form the barrier layer.

3. A method according to claim 1, wherein the barrier layer comprises at least one metal oxide.

4. A method according to claim 1, additionally comprising depositing copper on the barrier layer.

5. A method according to claim 2, wherein the oxide-forming or silicon oxide-forming metal is selected from the group consisting of aluminum, titanium, hafnium, zirconium and tantalum.

6. A method according to claim 2, wherein the oxide-forming metal is aluminum.

7. A method according to claim 1, wherein the gas is selected from the group consisting of nitrogen, argon, and mixtures thereof.

8. A method according to claim 1, wherein the gas is nitrogen.

9. A method according to claim 1, wherein the dielectric comprises an organosiloxane polymer.

10. A method according to claim 1, wherein the dielectric comprises a hybrid organosiloxane polymer.

11. A method for preventing migration of metal ions into a dielectric layer comprising a low-κ siloxane polymer, the method comprising treating at least one surface of the dielectric layer with an ammonia plasma and forming a barrier layer comprising at least one metal on the treated surface;
whereby the barrier layer prevents migration of metal ions into the dielectric layer.

12. A method according to claim 11, wherein forming a barrier layer comprises depositing at least one metal on the treated surface.

13. A method according to claim 11, wherein the barrier layer comprises at least one metal nitride.

14. A method according to claim 11, wherein the at least one metal is selected from tantalum, titanium and mixtures thereof.

15. A method according to claim 11, additionally comprising depositing copper over the barrier layer.

16. A method for preventing migration of metal ions into a dielectric layer comprising a low-κ siloxane polymer, the method comprising treating at least one surface of the dielectric layer with a plasma other than an ammonia plasma and forming a barrier layer on the treated surface; whereby the barrier layer prevents migration of metal ions into the dielectric layer.

17. A method according to claim 15, wherein the plasma is a nitrogen plasma.

18. A method according to claim 15, wherein forming a barrier layer comprises depositing at least one metal on the treated surface.

19. A method according to claim 15, wherein the barrier layer comprises at least one metal nitride.

20. A method according to claim 17, wherein the at least one metal is selected from tantalum, titanium and mixtures thereof.

21. A method according to claim 15, additionally comprising depositing copper over the barrier layer.
